(19) United States
(12) Patent Application Publication
(10) Pub. No.: US 2025/0048683 A1
(43) Pub. Date: Feb. 6, 2025

(54) METHODS OF FORMING ELECTRONIC DEVICES HAVING A STRAINED TRANSISTOR CHANNEL

(71) Applicant: Applied Materials, Inc., Santa Clara, CA (US)

(72) Inventors: Srinivas Gandikota, Santa Clara, CA (US); Yogesh Sharma, Sunnyvale, CA (US); Tuerxun Ailihumaer, Santa Clara, CA (US); Yixiong Yang, Fremont, CA (US)

(73) Assignee: Applied Materials, Inc., Santa Clara, CA (US)

(21) Appl. No.: 18/788,544

(22) Filed: Jul. 30, 2024

Related U.S. Application Data
(60) Provisional application No. 63/530,056, filed on Jul. 31, 2023.

(51) Int. Cl. H01L 29/10; H01L 29/66

(52) U.S. Cl. CPC H01L 29/1054; H01L 29/66439; H01L 29/66795

(57) ABSTRACT

Embodiments of the disclosure provide methods of manufacturing electronic devices that meet compressive stress requirements for PMOS transistors and tensile stress requirements for NMOS transistors. Each P-metal stack and P-metal stack: is formed on a top surface of a channel located between a source and a drain on a semiconductor substrate, and comprises nanosheet channel layers and trenches between each nanosheet channel layer, and has at least one side defining a gate trench. Some embodiments include forming a work function layer in the channel and inducing a work function layer strain in the channel. Some embodiments include forming a gate metal fill layer on each of the P-metal stack and the N-metal stack and inducing a gate metal fill layer strain in the channel. The gate metal fill layer covers the at least one side of each of the P-metal stack and the N-metal stack and fills the gate trench.

### CROSS-REFERENCE TO RELATED APPLICATIONS

This application claims priority to U.S. Provisional Application No. 63/530,056, filed Jul. 31, 2023, the entire disclosure of which is hereby incorporated by reference herein.

### TECHNICAL FIELD

Embodiments of the present disclosure pertain to the field of electronic device manufacturing, and in particular, to transistors. More particularly, embodiments of the disclosure are directed to methods of manufacturing FinFET and GAA devices having a strained transistor channel.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

As device dimensions have shrunk, device geometries and materials have experienced difficulty maintaining switching speeds without incurring failures. Several new technologies emerged that allowed chip designers to continue shrinking gate lengths. Control of the dimensions of device structure is a key challenge for present and future technology generations.

For example, micro-electronic field effect transistors (e.g., complementary metal-oxide-semiconductor (CMOS) field effect transistors) may be formed on a substrate and cooperate to perform various functions within the circuit. A CMOS transistor comprises a gate structure disposed over a channel region formed between source and drain regions of the transistor. The gate structure generally comprises a gate electrode and a gate dielectric. The gate electrode is disposed over the gate dielectric and, in operation, is used to control a flow of charge carriers (i.e., electric current) in the channel region beneath the gate dielectric.

It remains a challenge to induce stress/strain in the transistor channel throughout the migration of transistor technology from planar FET to FinFET to GAA devices, such as negative metal-oxide-semiconductor (NMOS) transistors and positive metal-oxide-semiconductor (PMOS) transistors.

It is thought that electron mobility (in NMOS transistors) and hole mobility (in PMOS transistors) can be increased by changing the silicon atom arrangement of crystal lattice in the transistor channel by inducing stress (or strain). For example, in PMOS transistors, the holes move with bond coupling. It is thought that increasing hole mobility and inducing compressive stress in the transistor channel can be achieved by decreasing longitudinal atomic spacing. In NMOS transistors, for example, the electrons move with drift and diffusion. It is thought that increasing electron mobility and inducing tensile stress in the transistor channel can be achieved by increasing longitudinal atomic spacing.

There are two conventional approaches to induce stress into the transistor channel: a biaxial global strain process and a uniaxial local strain process.

In a typical biaxial global strain process, the silicon crystal lattice can be mechanically compressed and/or stretched to induce strain by various processes. For example, biaxial global strain has been achieved by epitaxially growing a thin silicon (Si) layer on a relaxed silicon germanium (SiGe) substrate. Due to the lattice mismatch between Si and SiGe, the Si lattice is biaxially tensile strained along the interface plane. Alternatively, biaxial global strain can be introduced after the wafer has completely been processed. This is realized by thinning the wafer to less than 10 μm and transferring it to a polymer film, for example. After transferring the wafer, mechanically straining the Si membrane allows uniaxial and biaxial strain parallel to the substrate surface without inducing defects, e.g., vacancies, in the Si layer. The mechanically strained wafer can be bonded to a final substrate safely, as long as the strain level stays within the elastic limit.

One disadvantage of conventional global strain techniques is that such techniques only induce one type of strain: compress stress/strain or tensile stress/strain, but not both. Uniaxial local strain processes have been developed in an attempt to address the disadvantages of conventional global strain techniques.

In a typical uniaxial local strain process, silicon germanium (SiGe) is integrated into the source and drain regions of the PMOS transistors and silicon carbide (SiC) is integrated into the source and drain regions of the NMOS transistors.

However, it remains a challenge to induce and/or maintain strain in the transistor channel in GAA devices, especially in trenches between nanosheets due to spacing constraints. Specifically, for PMOS transistors, the compressive stress achieved by the two conventional approaches to induce stress into the transistor channel is much higher than desired as measured by gigapascals, due to higher electron mobility but lower hole mobility. For NMOS transistors, the tensile stress achieved by the two conventional processes into the transistor channel is undesirable, due to low electron mobility as measured by Ron DIBL. Ron DIBL is the on-resistance versus drain induced barrier lowering plot, which is a metric for transistor performance measurement. Lower Ron at constant DIBL means a better performance.

Accordingly, there is a need for improved methods of manufacturing electronic devices that meet compressive stress requirements for PMOS transistors and tensile stress requirements for NMOS transistors.

### SUMMARY

One or more embodiments of the disclosure are directed to a method of manufacturing an electronic device. The method comprises forming a P-metal stack and an N-metal stack on a semiconductor substrate. Each of the P-metal stack and the N-metal stack are formed on a top surface of a channel located between a source and a drain on the semiconductor substrate. Each of the P-metal stack and the N-metal stack comprise nanosheet channel layers and trenches between each nanosheet channel layer. The method further comprises forming a work function layer in the channel between the nanosheet channel layers in each of the trenches and inducing a work function layer strain in the channel. Each of the P-metal stack and the N-metal stack independently have a compressive stress and a tensile stress, respectively, in a range of from of 1 gigapascal (GPa) to 2 GPa.

Additional embodiments of the disclosure are directed to a method of manufacturing an electronic device. The method comprises forming a P-metal stack and an N-metal stack on a semiconductor substrate. Each of the P-metal stack and the N-metal stack are formed on a top surface of a channel located between a source and a drain on the semiconductor substrate. Each of the P-metal stack and the N-metal stack comprise nanosheet channel layers and trenches between each nanosheet channel layer, each of the P-metal stack and the N-metal stack having at least one side, the at least one side defining a gate trench; and forming a gate metal fill layer on each of the P-metal stack and the N-metal stack and inducing a gate metal fill layer strain in the channel. The gate metal fill layer covers the at least one side of each of the P-metal stack and the N-metal stack and fills the gate trench. The P-metal stack has a compressive stress in a range of from of −0.1 GPa to −3.1 GPa and the N-metal stack has a tensile stress of greater than or equal to 2 GPa.

Further embodiments of the disclosure are directed to a method of manufacturing an electronic device. The method comprises forming a P-metal stack and an N-metal stack on a semiconductor substrate. Each of the P-metal stack and the N-metal stack are formed on a top surface of a channel located between a source and a drain on the semiconductor substrate. Each of the P-metal stack and the P-metal stack comprise nanosheet channel layers and trenches between each nanosheet channel layer, and each of the P-metal stack and the N-metal stack have at least one side, the at least one side defining a gate trench. The method further comprises forming a work function layer in the channel between the nanosheet channel layers in each of the trenches and inducing a work function layer strain in the channel, forming the work function layer comprising a thermal process. The method further comprises forming a gate metal fill layer on each of the P-metal stack and the N-metal stack and inducing a gate metal fill layer strain in the channel. The gate metal fill layer covers the at least one side of each of the P-metal stack and the N-metal stack and fills the gate trench.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The embodiments as described herein are illustrated by way of example and not limitation in the figures of the accompanying drawings in which like references indicate similar elements.

FIG. 1A illustrates a process flow diagram of a method of manufacturing an electronic device according to one or more embodiments of the present disclosure;

FIG. 1B illustrates a process flow diagram of a method of manufacturing an electronic device according to one or more embodiments of the present disclosure;

FIG. 1C illustrates a process flow diagram of a method of manufacturing an electronic device according to one or more embodiments of the present disclosure;

FIG. 2A illustrates a cross-sectional view of a semiconductor substrate according to one or more embodiments of the present disclosure;

FIG. 2B illustrates a cross-sectional view of a semiconductor substrate according to one or more embodiments of the present disclosure;

FIG. 2C illustrates a cross-sectional view of a semiconductor substrate according to one or more embodiments of the present disclosure;

FIG. 2D illustrates a cross-sectional view of a semiconductor substrate according to one or more embodiments of the present disclosure;

FIG. 2E illustrates a cross-sectional view of a semiconductor substrate after forming a work function layer and inducing a work function layer strain in the channel;

FIG. 2F illustrates another cross-sectional view of a semiconductor substrate after forming a work function layer and inducing a work function layer strain in the channel;

FIG. 2G illustrates a cross-sectional view of the semiconductor substrate of after forming a work function layer and forming a gate metal fill layer on the work function layer, inducing a work function layer strain and a gate metal fill layer strain in the channel; and

FIG. 3 illustrates a cluster tool according to one or more embodiments of the present disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, −5%, −2%, or −1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated ID. Drain-to-source voltage is designated VDS. By applying voltage to gate (G), the current entering the channel at the drain (i.e. ID) can be controlled.

The metal-oxide-semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs or nanosheets, bar-shaped channels, or other suitable channel configurations known to one of skill in the art.

In one or more embodiments, after implementing the methods described in the present disclosure, the channel region of the GAA transistor has a stress that ranges from a high tensile stress (e.g., greater than or equal to 1 gigapascal (GPa)) to a compressive stress (e.g., a negative GPa). In one or more specific embodiments, after implementing the methods described in the present disclosure, advantageously, the channel region of the N-metal stack has a high tensile stress (e.g., greater than or equal to 1 gigapascal (GPa)) and the channel region of the P-metal stack has a compressive stress (e.g., a negative GPa).

In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Embodiments of the present disclosure advantageously provide methods of manufacturing electronic devices that increase electron mobility (in NMOS transistors) and hole mobility (in PMOS transistors) by straining the transistor channel. Some embodiments advantageously provide methods of manufacturing electronic devices that meet compressive stress requirements for PMOS transistors and tensile stress requirements for NMOS transistors. Embodiments of the disclosure address the challenges of conventional biaxial global strain processes and uniaxial local strain processes due to a new integration scheme.

The inventors have advantageously developed two independent processes that induce stress/strain into the transistor channel in order to meet compressive stress requirements for PMOS transistors and tensile stress requirements for NMOS transistors.

As described herein, forming the work function layer and inducing a work function layer strain may be referred to as the “first strain inducing process.” As described herein, forming the gate metal fill layer and inducing a gate metal fill layer strain may be referred to as the “second strain inducing process.” The designations of the “first strain inducing process” and the “second strain inducing process” are used for illustrative purposes to describe the respective processes in the order in which they appear in the Figures. It is to be understood that the processes developed by the inventors (the “first strain inducing process” and the “second strain inducing process”) can be implemented separately or together.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications. In one or more illustrated embodiments, like references indicate similar elements, unless specified otherwise.

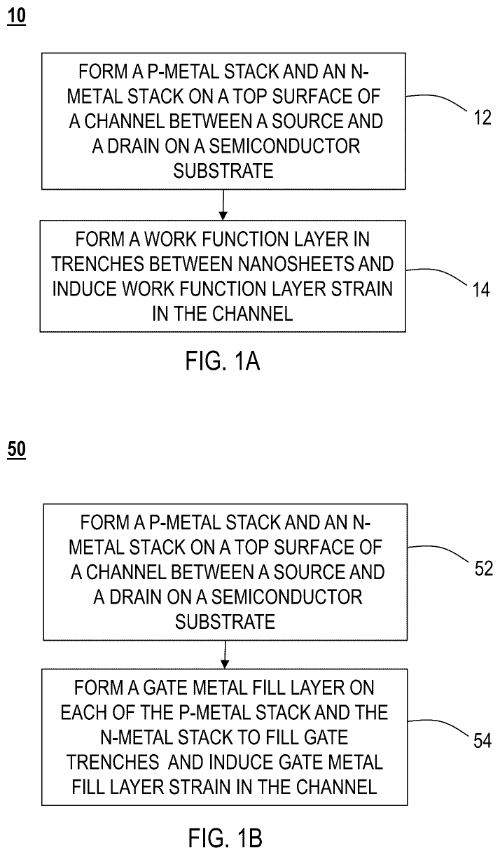

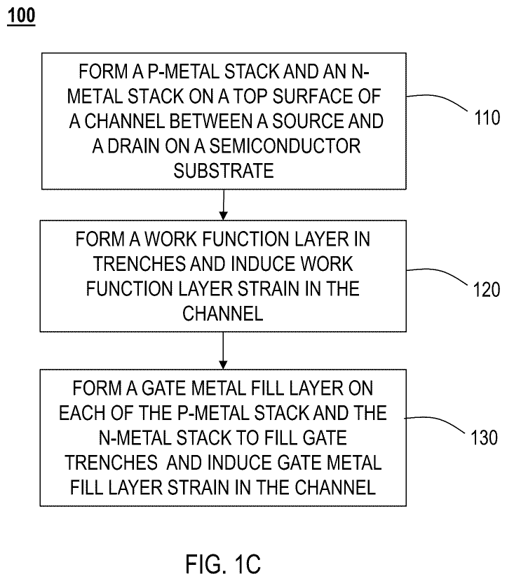

FIGS. 1A, 11B, and 1C independently illustrate process flow diagrams of a method of manufacturing an electronic device according to one or more embodiments of the present disclosure. FIG. 1A illustrates method 10. FIG. 1B illustrates method 50. FIG. 1C illustrates method 100.

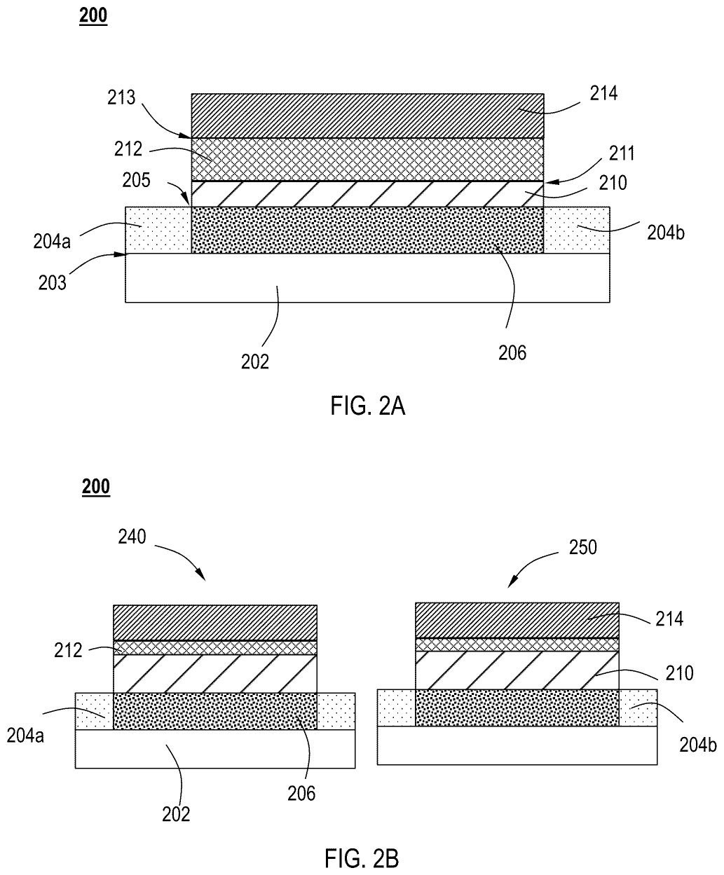

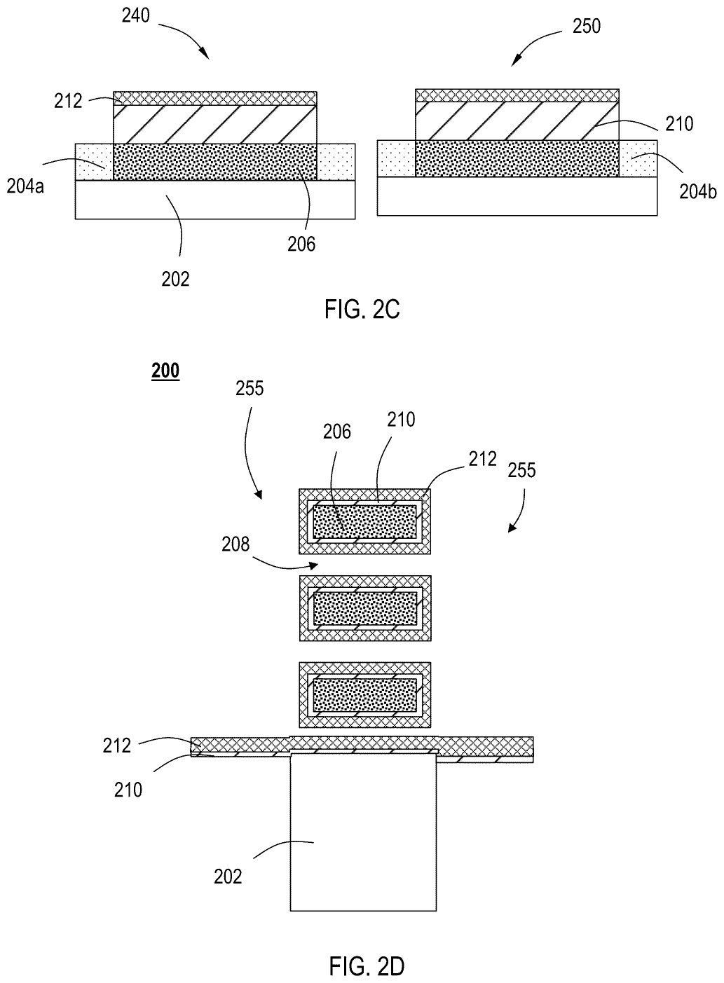

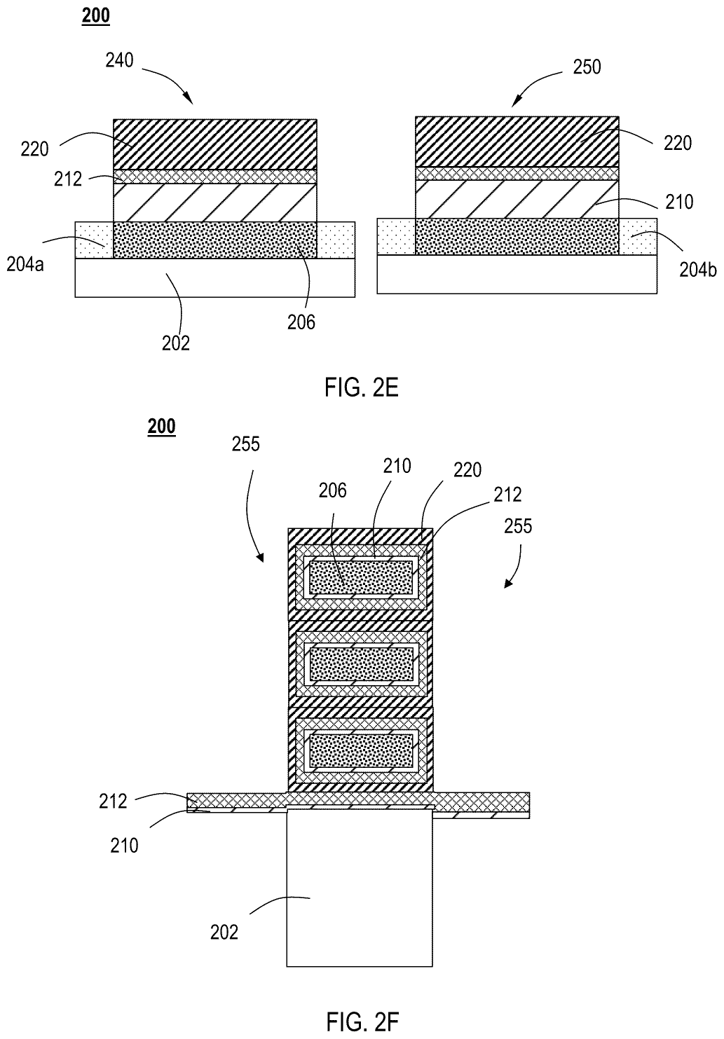

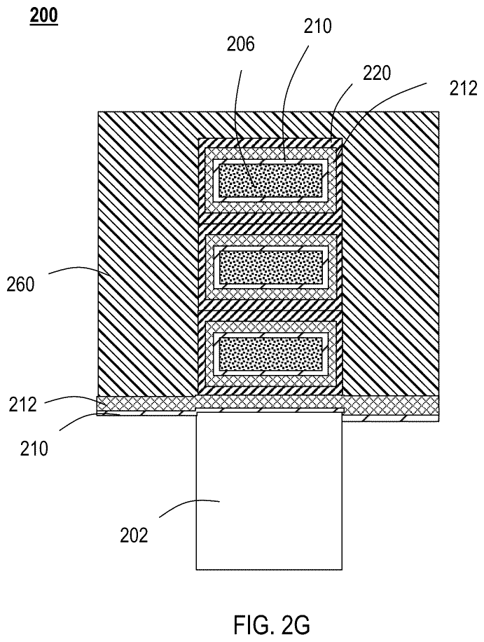

FIGS. 2A-2B are cross-sectional views of an electronic device (e.g., a transistor such as a FinFET or GAA) 200 according to one or more embodiments. FIGS. 2A-2C illustrate a process flow of forming a P-metal stack and an N-metal stack on a semiconductor substrate.

The electronic devices 200 shown in FIGS. 2E-2G may be manufactured by methods 10, 50, and 100 described herein.

Referring to FIGS. 2A-2G, in one or more embodiments, the electronic device 200 comprises a semiconductor substrate 202 having a top surface 203. The semiconductor substrate 202 can be any suitable substrate material. In one or more embodiments, the semiconductor substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the semiconductor substrate 202 comprises one or more of silicon (Si), germanium (Ge), gallium (Ga), arsenic (As), indium (In), phosphorus (P), or selenium (Se). Although a few examples of materials from which the semiconductor substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the semiconductor substrate 202 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more embodiments, a source region 204a is on the top surface 203 of the semiconductor substrate 202. In one or more embodiments, the source region 204a has a source and a source contact (not illustrated). A drain region 204b is on the top surface 203 of the semiconductor substrate 202 opposite the source region 204a. In one or more embodiments, the drain region 204b has a drain and a drain contact (not illustrated).

In one or more embodiments, the source region 204a and/or the drain region 204b can be any suitable material known to the skilled artisan. In one or more embodiments, the source region 204a and/or the drain region 204b may have more than one layer. For example, the source region 204a and/or the drain region 204b may independently comprise three layers. In one or more embodiments, the source region 204a and the drain region 204b may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), or zirconium (Zr). In some embodiments, the source region 204a and the drain region 204b may independently comprise a bottom layer of silicon with doped epi (e.g., SiGe, SiP, and the like), a second layer of silicide, which may contain nickel (Ni), titanium (Ti), aluminum (Al), and the like, and a third, or top, layer which may be a metal such as, but not limited to, cobalt, tungsten, ruthenium, and the like. In some embodiments, the source region 204a and the drain region 204b may be raised source/drain regions formed by EPI growth.

In one or more embodiments, the source contact and/or the drain contact may independently be selected from one or more of nitrogen (N), copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt). In one or more embodiments, formation of the source contact and/or the drain contact is conducted by any suitable process known to the skilled artisan, including, but not limited to ALD, CVD, PVD, MBE, MOCVD, spin-on, or other insulating layer deposition techniques known to the skilled artisan.

In one or more embodiments, a channel 206 is located between the source 204a and the drain 204b. As shown in FIGS. 2F and 2G, the channel 206 comprises a plurality of nanosheets. As used herein, the terms “channel 206,” “transistor channel 206,” “plurality of nanosheets 206,” and “plurality of nanosheet channel layers 206” may be used interchangeably. The channel 206 may include any suitable material known to the skilled artisan. In one or more embodiments, the channel 206 comprises silicon (Si).

Each of the methods described herein (e.g., method 10, 50, and 100) include forming a P-metal stack and an N-metal stack on a semiconductor substrate (operation 12 of method 10, operation 52 of method 50, and operation 110 of method 100).

Each of the P-metal stack and the N-metal stacks are formed on the top surface 205 of the channel 206 located between the source 204a and the drain 204b on the semiconductor substrate 202. In some embodiments, forming each of the P-metal stack and the N-metal stack comprises: depositing an interfacial layer 210 on the top surface 205 of the channel 206; depositing a high-K dielectric layer 212 on the interfacial layer 210; and depositing a dipole layer 214 to a predetermined thickness on the high-K dielectric layer 212.

Referring to FIGS. 1A-1C and 2A-2G, in some embodiments, the interfacial layer 210 is deposited on the top surface 205 of the channel 206 using a deposition technique, such as, but not limited to, ALD, CVD, PVD, MBE, MOCVD, spin-on, or other insulating layer deposition techniques known to the skilled artisan. In one or more embodiments, the interfacial layer 210 comprises a silicon oxide (SiOx) layer formed on doped silicon or undoped silicon. In one or more embodiments, the interfacial layer 210 may be formed by etching and an oxide forming on the surface. In one or more embodiments, the interfacial layer 210 has a thickness in a range of 1 Å to 10 Å.

In some embodiments, a wet chemistry technique is performed to form the interfacial layer 210. The wet chemistry technique may be any suitable technique known to the skilled artisan. In some embodiments, the wet chemistry technique includes a pre-clean process. In some embodiments, the pre-clean process includes using a SC-1 solution comprising one or more of ozone, ammonium hydroxide or hydrogen peroxide. In some embodiments, the pre-clean process includes using a SC-1 solution without ozone, ammonium hydroxide or hydrogen peroxide. In some embodiments, after using the SC-1 solution, the pre-clean process includes using dilute hydrofluoric acid (dilute HF), including greater than 100:1, such as 130:1 dilute HF, to etch away native oxide on the semiconductor substrate 202 to form a hydrophobic surface (i.e., the interfacial layer 210).

In some embodiments, a rapid thermal process (RTP) is used to form the interfacial layer 210. The RTP may be any suitable process known to the skilled artisan. In some embodiments, the RTP is a thermal oxidation process in which a silicon oxide (SiOx) layer, e.g., the interfacial layer 210 is grown on the semiconductor substrate 202.

In some embodiments, the high-κ dielectric layer 212 is deposited on the interfacial layer 210 using a deposition technique, such as, but not limited to, ALD, CVD, PVD, MBE, MOCVD, spin-on, or other insulating layer deposition techniques known to the skilled artisan. In some embodiments, the high-κ dielectric layer 212 is conformally deposited by ALD.

The high-κ dielectric layer 212 comprises one or more of hafnium oxide (HfOx), hafnium zirconium oxide (HfZrOx), zirconium oxide (ZrOx), nitrogen-doped hafnium oxide (HfOx), nitrogen-doped hafnium zirconium oxide (HfZrOx), and nitrogen-doped zirconium oxide (ZrOx).

The high-κ dielectric layer 212 may have any suitable thickness. In some embodiments, the high-κ dielectric layer 212 has a thickness in a range of from 10 Å to 20 Å.

In some embodiments, the dipole layer 214 is deposited a top surface 213 of the high-κ dielectric layer 212 using a deposition technique, such as, but not limited to, ALD, CVD, PVD, MBE, MOCVD, spin-on, or other insulating layer deposition techniques known to the skilled artisan.

In some embodiments, depositing the dipole layer 214 comprises exposing the semiconductor substrate 202 to a pulse of a metal-containing precursor and a pulse of a reactant by an atomic layer deposition (ALD) process or a chemical vapor deposition (CVD) process. In some embodiments, the semiconductor substrate 202 is purged after each pulse. In one or more specific embodiments, the dipole layer 214 is deposited by atomic layer deposition (ALD).

In one or more embodiments, the dipole layer 214 is deposited by atomic layer deposition (ALD) at a temperature in the range of about 200° C. to about 600° C. In one or more embodiments, the dipole layer 214 is deposited by atomic layer deposition (ALD) at a temperature less than or equal to about 450° C.

The dipole layer 214 may have any suitable thickness. In one or more embodiments, the dipole layer 214 has a thickness in a range of 1 Å to 10 Å, or in a range of 2 Å to 5 Å. In one or more specific embodiments, the dipole layer 214 has a thickness in a range of 3 Å to 4 Å. The dipole layer 214 may be deposited as a single layer or as a multilayer film.

In some embodiments, the dipole layer 214 comprises one or more of a metal layer, a metal oxide layer, or a metal nitride layer.

In some embodiments, the metal-containing precursor used to form the dipole layer 214 comprises one or more of titanium (Ti), tantalum (Ta), aluminum (Al), niobium (Nb), antimony (Sb), tellurium (Te), germanium (Ge), gallium (Ga), lanthanum (La), yttrium (Y), strontium (Sr), scandium (Sc), or boron (B).

In some embodiments, the reactant is a hydrogen-containing reactant to form a dipole layer 214 comprising a pure metal layer. In some embodiments, the hydrogen-containing reactant used to form the dipole layer 214 comprises one or more of hydrogen (H₂) or deuterium (²H).

In some embodiments, the reactant is an oxygen-containing reactant to form a dipole layer 214 comprising a metal oxide layer. In some embodiments, the oxygen-containing reactant used to form the dipole layer 214 comprises one or more of oxygen (O₂), ozone (O₃), or water (H₂O).

In some embodiments, the reactant is a nitrogen-containing reactant to form a dipole layer 214 comprising a metal nitride layer.

In some embodiments, the nitrogen-containing reactant used to form the dipole layer 214 comprises one or more of nitrogen (N₂), ammonia (NH₃), hydrazine (N₂H₄), a co-flow of nitrogen radicals (N₂*) and hydrogen radicals (H*), a co-flow of nitrogen radicals (N₂*) and hydrogen (H₂) gas, or a co-flow of nitrogen radicals (N₂*) and deuterium (²H) gas.

In some embodiments the nitrogen-containing reactant used to form the dipole layer 214 comprises a substituted or unsubstituted alkyl hydrazine. In some embodiments, the alkyl hydrazine comprises in a range of from 1 carbon to 6 carbons.

In one or more embodiments, the alkyl hydrazine is t-butyl hydrazine. In some embodiments, the nitrogen-containing reactant comprises a plasma. In some embodiments, the nitrogen-containing reactant comprises ammonia (NH₃).

In FIGS. 2B, 2C, and 2E, an N-metal stack 240 and a P-metal stack 250 are shown. In one or more embodiments, the stack on the left side is the N-metal stack 240 and the stack on the right side is the P-metal stack 250. The skilled artisan recognizes that the either the left side or the right side may comprise either of the N-metal stack 240 or the P-metal stack 250, and the disclosure is not limited to the illustrated embodiments.

In one or more embodiments, the channel 206 comprises n-type material and the dipole layer 214 comprises one or more of lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), lutetium (Lu), magnesium (Mg), scandium (Sc), strontium (Sr), yttrium (Y), zirconium (Zr), or caesium (Cs).

In one or more embodiments, the channel 206 comprises p-type material and the dipole layer 214 comprises one or more of aluminum (Al), titanium (Ti), gallium (Ga), germanium (Ge), selenium (Se), indium (In), tin (Sn), antimony (Sb), tellurium (Te), tantalum (Ta), tungsten (W), or molybdenum (Mo).

The methods includes annealing the P-metal stack 250 and the N-metal stack 240 at a temperature of less than or equal to 1000° C. to drive in metal atoms from the dipole layer and densify the high-κ dielectric layer (not illustrated). In some embodiments, the methods comprise annealing the P-metal stack 250 and the N-metal stack 240 at a temperature of less than or equal to 950° C. In some embodiments, the temperature is in a range of from 500° C. to 1000° C., including in a range of from 600° C. to 1000° C., in a range of from 700° C. to 1000° C., in a range of from 750° C. to 950° C., or in a range of from 800° C. to 900° C.

In one or more embodiments, the dipole layer 214 on one or more of the P-metal stack 250 or the N-metal stack 240 is removed by a selective etching process. In FIG. 2C, for example, the dipole layer 214 is removed by a selective etching process from each of the P-metal stack 250 and the N-metal stack 240.

The etching process can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric aid or hydrogen peroxide. It has advantageously been found that using a SC-1 solution or a SC-2 solution selectively etches the deposited dipole layer 214 from one of the P-metal stack or the N-metal stack without etching a portion of the interfacial layer 210.

FIG. 2D illustrates another cross-sectional view of the semiconductor substrate 202 of FIG. 2C. In FIG. 2D, each of the plurality of nanosheet channel layers 206 are encapsulated by the interfacial layer 210, and the high-κ dielectric layer 212 on the interfacial layer 210. FIG. 2D illustrates trenches 208 between each of the plurality of nanosheet channel layers 206. In one or more embodiments, there is a gate trench 255 on at least one side of the channel 206. In FIG. 2D, for example, there is a gate trench 255 on each side of the channel 206.

Referring to FIGS. 1A and 2E-2F, the method 10 includes, at operation 14, forming a work function layer 220 in the channel 206 (e.g., between the nanosheet channel layers 206) and inducing a work function layer strain in the channel 206. FIGS. 1A, 1C, and 2E-2G illustrate at least the “first strain inducing process.”

In FIG. 2F, all sides of the channel 206 are covered. Each of the plurality of nanosheet channel layers 206 comprise silicon (Si). In FIG. 2F, each of the plurality of nanosheet channel layers 206 are encapsulated by the interfacial layer 210, the high-κ dielectric layer 212 on the interfacial layer 210, and the work function layer 220 on the high-κ dielectric layer 212. In one or more embodiments, there is a gate trench 255 on at least one side of the channel 206. In the illustrated embodiment of FIG. 2F, for example, there is a gate trench 255 on each side of the channel 206.

The work function layer 220 may be formed by any suitable process known to the skilled artisan. The work function layer 220 may be formed by any suitable process on the N-metal stack 240. In one or more embodiments, forming the work function layer 220 on the P-metal stack 250 comprises a thermal process. The process parameters of the thermal process may be optimized or modified based on the specific application.

As used herein, the term “thermal process” refers to a deposition technique that does not involve the use of plasma. As used herein, the term “plasma” refers to a composition have ionically charged species and uncharged neutral and radical species. In one or more embodiments, the ionically charged species of the plasma is neutralized by optimizing pressure in the processing chamber. In embodiments where the ionically charged species of the plasma is neutralized, the plasma comprises a greater percentage of radicals, and may be referred to as a “radical-based plasma” or a “radical-based process.” In some embodiments, the radical-based plasma is generated by a remote plasma source. Without intending to be bound by theory, it is thought that radical-based plasma generated by a remote plasma source eliminates ionically charged species of the plasma, such that the plasma comprises a greater percentage of radicals.

The radical-based plasma may include any radical species. In some embodiments, the radical-based plasma comprises one or more of nitrogen radicals (N₂*) or hydrogen radicals (H*). The composition of the mixture of nitrogen radicals (N₂*) and hydrogen radicals (H*) may include any suitable ratio of nitrogen radicals (N₂*) to hydrogen radicals (H*) and the ratio may be optimized or modified based on the specific application.

In one or more embodiments, the work function layer 220 is formed in the channel 206 (e.g., in the trenches 208 between the nanosheet channel layers 206) after depositing the high-κ dielectric layer 212. FIGS. 2E and 2F illustrate the work function layer 220 formed on the high-κ dielectric layer 212.

Without intending to be bound by theory, in one or more embodiments, it is thought that if the dipole meets the required threshold voltage (Vₜ) for the specific application, the work function layer 220 may be replaced with a pure mid-gap metal material with a tunable stress.

In one or more embodiments, the methods further comprise forming a titanium nitride (TiN) layer in one or more of the trenches 208 of the channel 206, such as, for example, the channel 206 of the P-metal stack 250, prior to forming the work function layer 220 (not illustrated).

The work function layer 220 may comprise any suitable metal known to the skilled artisan. The work function layer 220 may be formed by any suitable metal-containing precursor, including, but not limited to an organometallic precursor and/or a metal halide precursor. In one or more embodiments, the metal-containing precursor includes, but is not limited to, molybdenum (Mo), tungsten (W), titanium (Ti), aluminum (AI), ruthenium (Ru), iridium (Ir), tantalum (Ta), niobium (Nb), vanadium (V), or rhenium (Re).

In some embodiments, the work function layer 220 comprises one or more of a P-metal or an N-metal. In one or more embodiments, the work function layer 220 comprises a P-metal. In embodiments where the work function layer 220 comprises a P-metal, the P-metal includes, for example, any suitable high electronegativity metal nitride material. In embodiments where the work function layer 220 comprises a P-metal, the P-metal comprises one or more of molybdenum (Mo), molybdenum nitride (MoN), molybdenum oxynitride (MoON), or molybdenum carbonitride (MoCN).

In some embodiments, the work function layer 220 comprises an N-metal. In embodiments where the work function layer 220 comprises an N-metal, the N-metal includes, for example, any suitable electropositive refractive metals. In some embodiments, the N-metal comprises titanium aluminum nitride (TiAIN).

The work function layer 220 may have any suitable thickness. In one or more embodiments, the work function layer has a thickness in a range of from 10 Å to 30 Å. In one or more embodiments, the work function layer has a thickness of less than or equal to 30 Å, or less than or equal to 20 Å.

The P-metal stack 250 and/or the N-metal stack 240 may comprise any suitable P-metal, such as the P-metals described herein. The P-metal stack 250 and/or the N-metal stack 240 may comprise any suitable N-metal, such as the N-metals described herein.

In one or more embodiments, the methods further comprise forming a titanium nitride (TiN) layer, a TiN layer having an amorphous silicon (a-Si) capping layer thereon, or a titanium silicon nitride (TiSiN) layer in the trenches 208 of the channel 206, such as for example, the channel 206 of the N-metal stack 240 prior to forming the work function layer 220 (not illustrated).

In one or more embodiments, the work function layer 220 on the N-metal stack comprises titanium aluminum nitride (TiAIN). In one or more embodiments, the work function layer 220 on the N-metal stack comprises titanium aluminum nitride (TiAIN) formed by a thermal process.

It has been advantageously found that the work function materials described herein induce stress to the transistor channel 206 of the electronic device 200. As described herein, the work function layer strain from the “first strain inducing process” is a high tensile stress. Advantageously, each of the P-metal stack 250 and the N-metal stack 240 independently have a compressive stress and a tensile stress, respectively, in a range of from of 1 gigapascal (GPa) to 2 GPa when the work function layer 220 is deposited in the channel 206 (e.g., between the nanosheet channel layers 206 in each of the trenches 208) and inducing the work function layer strain in the channel 206.

Referring to FIGS. 1B and 2F, the method 50 includes, at operation 54, forming a gate metal fill layer 260 on each of the P-metal stack 250 and the N-metal stack 240 and inducing a gate metal fill layer strain in the channel 206, the gate metal fill layer 260 covering the at least one side of each of the P-metal stack and the N-metal stack and filling the gate trench 255.

Referring to FIGS. 1C and 2G, the method 100 includes, at operation 130, forming a gate metal fill layer 260 on the channel 206 (e.g., on the channel 206 of each of the P-metal stack 250 and the N-metal stack 240 and inducing a gate metal fill layer strain in the channel 206. In one or more embodiments, the gate metal fill layer 260 covers the at least one side of each of the channel 206 (e.g., the channel 206 of each of P-metal stack 250 and the N-metal stack 240). In one or more embodiments, in FIG. 2G, for example, the gate metal fill layer 260 fills the gate trench 255 on both sides of the channel 206. In some embodiments, the process of operation 54 of method 50 and the process of operation 130 of method 100 are the same. FIGS. 1B, 1C, and 2G illustrate at least the “second strain inducing process.” As described herein, the gate metal fill layer strain from the “second strain inducing process” is a compressive stress.

In FIG. 2G, all sides of the channel 206 are covered. Each of the plurality of nanosheet channel layers 206 comprise silicon (Si). In FIG. 2G, each of the plurality of nanosheet channel layers 206 are encapsulated by the interfacial layer 210, the high-κ dielectric layer 212 on the interfacial layer 210, the work function layer 220 on the high-κ dielectric layer 212, and the gate metal fill layer 260 on the work function layer 220.

In the illustrated embodiment of FIG. 2G, for example, the gate metal fill layer 260 covers all sides of the channel 206 and fills the gate trenches 255 on both sides of the channel 206. In one or more embodiments the gate metal fill layer 260 covers all of the sides of each of the P-metal stack 250 and the N-metal stack 240. In one or more embodiments, the gate metal fill layer 260 is a continuous layer.

In one or more embodiments, forming the gate metal fill layer 260 comprises a thermal process (as described herein) followed by a post-treatment process or a plasma-enhanced atomic layer deposition (PEALD) process.

In embodiments where forming the gate metal fill layer 260 comprises the thermal process followed by the post-treatment process, the post-treatment process comprises exposing the thermally deposited gate metal fill layer 260 to a plasma comprising one or more of argon (Ar) or hydrogen (H₂) at a plasma power in a range of from 150 W to 800 W to form a treated gate metal fill layer. In some embodiments, the Ar plasma is flowed in a range of from 0.5 standard liters per minute (slm) to 6 slm. In some embodiments, the H₂ plasma is flowed in a range of from 6 slm to 10 slm.

In one or more embodiments, the gate metal fill layer 260 is formed at a temperature in a range of from 150° C. to 500° C.

In one or more embodiments, forming the gate metal fill layer 260 comprises exposing the semiconductor substrate 202 to one or more of a molybdenum-containing precursor or a tungsten-containing precursor. The molybdenum-containing precursor and/or the tungsten-containing precursor may include any suitable precursor. In one or more embodiments, the molybdenum-containing precursor comprises one or more of molybdenum pentachloride (MoCl₅) or molybdenum dioxide dichloride (MoO₂Cl₂). In one or more embodiments, the tungsten-containing precursor comprises tungsten pentachloride (WCl₅), tungsten hexafluoride (WF₆), or tungsten oxychloride (WOₓCl_{y}).

Advantageously, forming the gate metal fill layer 260 induces a gate metal fill layer strain in the channel 206. The P-metal stack 250 advantageously has a compressive stress (e.g., a negative GPa) when the gate metal fill layer 260 is formed.

In embodiments where the gate metal fill layer 260 is formed by the methods described herein, advantageously, the electronic devices 200 meet compressive stress requirements for PMOS transistors and tensile stress requirements for NMOS transistors. In one or more embodiments, the P-metal stack 250 has a compressive stress in a range of from of −0.1 GPa to −3.1 GPa and the N-metal stack 240 has a tensile stress of greater than or equal to 2 GPa.

In one or more embodiments, the value of the compressive stress of the P-metal stack 250 varies based upon the thickness of the gate metal fill layer 260. Without intending to be bound by theory, it is thought that the compressive stress of the P-metal stack 250 increases as the thickness of the gate metal fill layer 260 increases.

The gate metal fill layer 260 can be deposited to any suitable thickness. In one or more embodiments, the gate metal fill layer 260 is deposited to a thickness of greater than or equal to 30 Å, greater than or equal to 50 Å, greater than or equal to 100 Å, greater than or equal to 150 Å, or greater than or equal to 200 Å.

In some embodiments, the P-metal stack 250 has a compressive stress of −1.7 GPa at 35 Å and a compressive stress of −0.6 GPa at 150 Å when the gate metal fill layer 260 is deposited by the thermal process using MoO₂Cl₂.

In some embodiments, the P-metal stack 250 has a compressive stress of −0.8 GPa at 35 Å and a compressive stress of −0.1 GPa at 150 Å when the gate metal fill layer 260 is deposited by the thermal process using MoCl₅.

In some embodiments, the P-metal stack 250 has a compressive stress of −1.8 GPa at 30 Å and a compressive stress of −1.0 GPa at 100 Å when the gate metal fill layer 260 is deposited by the PEALD process using MoO₂Cl₂.

In some embodiments, the P-metal stack 250 has a compressive stress of −0.96 GPa at about 42 Å and a compressive stress of −0.86 GPa at 90 Å when the gate metal fill layer 260 is deposited by the PEALD process using MoCl₅.

In one or more embodiments, method 100 includes forming the work function layer 220 (the “first strained inducing process”) by depositing the work function layer 220 to a thickness of less than or equal to 30 Å, less than or equal to 20 Å, or less than or equal to 10 Å by a thermal process and forming the gate metal fill layer 260 (the “second strain inducing process”) by forming the gate metal fill layer 260 to a thickness of greater than or equal to 30 Å, greater than or equal to 50 Å, greater than or equal to 100 Å, greater than or equal to 150 Å, or greater than or equal to 200 Å by a PEALD process.

Further aspects of the disclosure pertain to a method that is part of a gap fill process. In some embodiments, such as method 100, the work function layer 220 is deposited on all sides of the channel 206. In one or more embodiments, the work function layer 220 acts a liner, and the gate fill metal layer 260 is deposited on the work function layer 220. In one or more embodiments, the work function layer 220 is deposited to a thickness of less than or equal to 30 Å, less than or equal to 20 Å, or less than or equal to 10 Å by a thermal process and the gate metal fill layer 260 is deposited on the work function layer to a thickness of greater than or equal to 30 Å, greater than or equal to 50 Å, greater than or equal to 100 Å, greater than or equal to 150 Å, or greater than or equal to 200 Å by a PEALD process. It has been advantageously found that depositing the work function layer 220, followed by depositing the gate fill metal layer 260 on the work function layer 220, as in method 100, for example, advantageously induces compressive stress and tensile stress, respectively, that meets compressive stress requirements for PMOS transistors and tensile stress requirements for NMOS transistors.

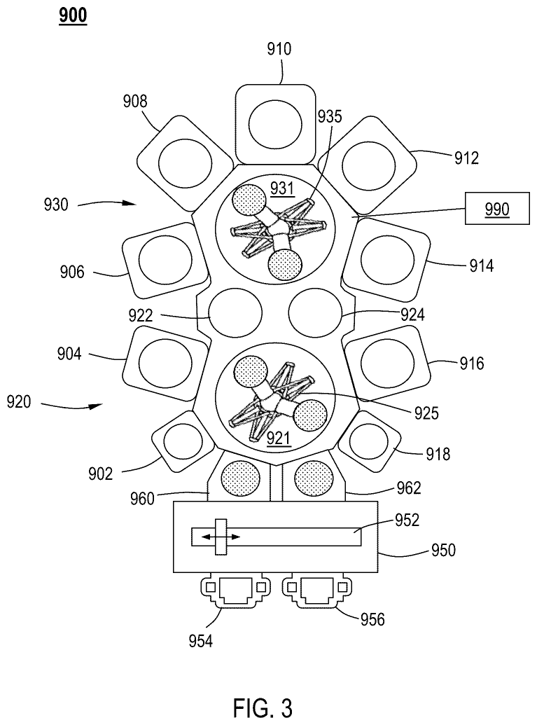

Additional embodiments of the disclosure are directed to processing tools (i.e., a cluster tool) 900 for the formation of the logic/memory devices and methods described, as shown in FIG. 3. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station 921, 931. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a thermal processing chamber, a plasma oxidation chamber, a plasma nitridation chamber, an atomic layer deposition (ALD) chamber, and a plasma-enhanced ALD (PEALD) chamber.

In one or more embodiments, the ALD chamber includes a single chamber for depositing an interfacial layer on the top surface of the channel; depositing a high-κ dielectric layer on the interfacial layer; and depositing a dipole layer to a predetermined thickness on the high-κ dielectric layer, such that there is no vacuum break in between the operations.

In one or more embodiments, the ALD chamber can include a single chamber for each of depositing an interfacial layer on the top surface of the channel; depositing a high-κ dielectric layer on the interfacial layer; and depositing a dipole layer to a predetermined thickness on the high-κ dielectric layer, such that there is a vacuum break in between at least one of the operations.

In one or more embodiments, the thermal processing chamber is used to form the work function layer 220. In one or more embodiments, the PEALD chamber is used to form the gate metal fill layer 260. In one or more embodiments, the thermal processing chamber and the PEALD chamber are connected, such that there is no vacuum break in between the respective operations.

In one or more embodiments, the thermal processing chamber and the PEALD chamber are isolated in a manner such that there is a vacuum break in between the respective operations.

The particular arrangement of process chambers and components can be varied depending on the cluster tool and should not be taken as limiting the scope of the disclosure.

In one or more embodiments, the cluster tool 900 includes a silicon dioxide (SiO₂) chamber to deposit silicon dioxide (SiO₂). The silicon dioxide (SiO₂) deposition chamber of some embodiments comprises an atomic layer deposition chamber, a plasma enhanced atomic layer deposition chamber, or a spatial atomic layer deposition chamber. In one or more embodiments, the cluster tool 900 includes a pre-cleaning chamber connected to the central transfer station.

In the embodiment shown in FIG. 3, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown in FIG. 3 has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or to allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the methods described herein, (e.g., method 10, 50, and/or 100), of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the methods described herein. In one or more embodiments, the controller causes the processing chamber to perform the operations of method 10. In one or more embodiments, the controller causes the processing chamber to perform the operations of method 50. In one or more embodiments, the controller causes the processing chamber to perform the operations of method 100.

In one or more embodiments, the processing tool 900 comprises a central transfer station 921, 931 comprising at least one robot 925, 935 configured to move a wafer; one or more of a rapid thermal processing (RTP) station, a decoupled plasma oxidation (DPO), or decoupled plasma nitridation (DPN) station connected to the central transfer station; an atomic layer deposition (ALD) station connected to the central transfer station; a thermal processing station; a plasma-enhanced ALD (PEALD) station; an optional pre-clean station connected to the central transfer station; and at least one controller connected to the one or more of the central transfer station, the RTP station, the DPO station, the DPN station, the ALD station or the optional pre-clean station. In one or more embodiments, the at least one controller has at least one configuration selected from: a configuration to move the wafer between stations using the robot; a configuration to perform a rapid thermal process; a configuration to perform a decoupled plasma process; a configuration to control a flow of an oxidizing gas into the RTP station or DPO station; a configuration to control a flow of a nitriding gas into the RTP station or DPN station; a configuration to deposit a silicon oxide film by atomic layer deposition; and a configuration to pre-clean the wafer.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing an electronic device, the method comprising:
forming a P-metal stack and an N-metal stack on a semiconductor substrate, each of the P-metal stack and the N-metal stack formed on a top surface of a channel located between a source and a drain on the semiconductor substrate, each of the P-metal stack and the P-metal stack comprising nanosheet channel layers and trenches between each nanosheet channel layer; and
forming a work function layer in the channel between the nanosheet channel layers in each of the trenches and inducing a work function layer strain in the channel, each of the P-metal stack and the N-metal stack independently having a compressive stress and a tensile stress, respectively, in a range of from of 1 gigapascal (GPa) to 2 GPa.

2. The method of claim 1, wherein forming each of the P-metal stack and the N-metal stack comprises: depositing an interfacial layer on the top surface of the channel; depositing a high-κ dielectric layer on the interfacial layer; and depositing a dipole layer on the high-κ dielectric layer.

3. The method of claim 2, wherein the work function layer is formed in the channel between the nanosheet channel layers after depositing the high-κ dielectric layer.

4. The method of claim 1, further comprising forming a titanium nitride (TiN) layer in one or more of the trenches of the P-metal stack prior to forming the work function layer.

5. The method of claim 1, wherein forming the work function layer on the P-metal stack comprises a thermal process.

6. The method of claim 5, wherein the work function layer comprises one or more of molybdenum (Mo), molybdenum nitride (MoN), molybdenum oxynitride (MoON), or molybdenum carbonitride (MoCN).

7. The method of claim 1, further comprising forming a titanium nitride (TiN) layer, a TiN layer having an amorphous silicon (a-Si) capping layer thereon, or a titanium silicon nitride (TiSiN) layer in the trenches of the N-metal stack prior to forming the work function layer.

8. The method of claim 1, wherein forming the work function layer on the N-metal stack comprises titanium aluminum nitride (TiAIN) formed by a thermal process.

9. A method of manufacturing an electronic device, the method comprising:
forming a P-metal stack and an N-metal stack on a semiconductor substrate, each of the P-metal stack and the N-metal stack formed on a top surface of a channel located between a source and a drain on the semiconductor substrate, each of the P-metal stack and the P-metal stack comprising nanosheet channel layers and trenches between each nanosheet channel layer, each of the P-metal stack and the N-metal stack having at least one side, the at least one side defining a gate trench; and
forming a gate metal fill layer on each of the P-metal stack and the N-metal stack and inducing a gate metal fill layer strain in the channel, the gate metal fill layer covering the at least one side of each of the P-metal stack and the N-metal stack and filling the gate trench, the P-metal stack having a compressive stress in a range of from of −0.1 GPa to −3.1 GPa and the N-metal stack having a tensile stress of greater than or equal to 2 GPa.

10. The method of claim 9, wherein forming the gate metal fill layer comprises a thermal process followed by a post-treatment process or a plasma-enhanced atomic layer deposition (PEALD) process.

11. The method of claim 10, wherein the post-treatment process comprises exposing the thermally deposited gate metal fill layer to a plasma comprising one or more of argon (Ar) or hydrogen (H₂) at a plasma power in a range of from 150 W to 800 W to form a treated gate metal fill layer.

12. The method of claim 11, comprising flowing the Ar plasma in a range of from 0.5 standard liters per minute (slm) to 6 slm.

13. The method of claim 11, comprising flowing the H₂ plasma in a range of from 6 slm to 10 slm.

14. The method of claim 10, wherein forming the gate metal fill layer comprises exposing the semiconductor substrate to one or more of a molybdenum-containing precursor or a tungsten-containing precursor.

15. The method of claim 14, wherein the molybdenum-containing precursor comprises one or more of molybdenum pentachloride (MoCl₅) or molybdenum dioxide dichloride (MoO₂Cl₂).

16. The method of claim 14, wherein the P-metal stack has a compressive stress of −1.7 GPa at 35 Å and a compressive stress of −0.6 GPa at 150 Å when the gate metal fill layer is deposited by the thermal process using MoO₂Cl₂.

17. The method of claim 14, wherein the P-metal stack has a compressive stress of −0.8 GPa at 35 Å and a compressive stress of −0.1 GPa at 150 Å when the gate metal fill layer is deposited by the thermal process using MoCl₅.

18. The method of claim 14, wherein the P-metal stack has a compressive stress of −1.8 GPa at 30 Å and a compressive stress of −1.0 GPa at 100 Å when the gate metal fill layer is deposited by the PEALD process using MoO₂Cl₂.

19. The method of claim 14, wherein the P-metal stack has a compressive stress of −0.96 GPa at about 42 Å and a compressive stress of −0.86 GPa at 90 Å when the gate metal fill layer is deposited by the PEALD process using MoCl₅.

20. A method of manufacturing an electronic device, the method comprising:
forming a P-metal stack and an N-metal stack on a semiconductor substrate, each of the P-metal stack and the N-metal stack formed on a top surface of a channel located between a source and a drain on the semiconductor substrate, each of the P-metal stack and the P-metal stack comprising nanosheet channel layers and trenches between each nanosheet channel layer, each of the P-metal stack and the N-metal stack having at least one side, the at least one side defining a gate trench;
forming a work function layer in the channel between the nanosheet channel layers in each of the trenches and inducing a work function layer strain in the channel, forming the work function layer comprising a thermal process; and
forming a gate metal fill layer on each of the P-metal stack and the N-metal stack and inducing a gate metal fill layer strain in the channel, the gate metal fill layer covering the at least one side of each of the P-metal stack and the N-metal stack and filling the gate trench, forming the gate metal fill layer comprising a plasma-enhanced atomic layer deposition (PEALD) process, the N-metal stack having a tensile stress in a range of greater than or equal to 2 GPa, and the P-metal stack having a compressive stress in a range of from of −0.1 GPa to −3.1 GPa.
